(19) United States
(12) Patent Application Publication
(10) Pub. No.: US 2025/0102920 A1
(43) Pub. Date: Mar. 27, 2025

(54) METHOD FOR HEATING AN OPTICAL ELEMENT, AND OPTICAL SYSTEM

(71) Applicant: Carl Zeiss SMT GmbH, Oberkochen (DE)

(72) Inventors: Malte LANGENHORST, Aalen (DE); Maximilian HENNING, Huettlingen (DE); Matthias HOLTKEMPER, Aalen (DE); Werner WEISS, Ulm (DE); Fabian LETSCHER, Oberkochen (DE); André DIRAUF, Aalen (DE)

(21) Appl. No.: 18/976,482

(22) Filed: Dec. 11, 2024

Related U.S. Application Data
(63) Continuation of application No. PCT/EP2023/061647, filed on May 3, 2023.

(30) Foreign Application Priority Data
Jun. 14, 2022 (DE) 10 2022 114 974.9
Nov. 28, 2022 (DE) 10 2022 131 353.0

(51) Int. Cl. G03F 7/00; G02B 7/18; G02B 27/00

(52) U.S. Cl. CPC G03F 7/70258; G02B 7/1815; G02B 27/0043; G03F 7/70233; G03F 7/70891

(57) ABSTRACT

A method for heating an optical element in an optical system, such as in a microlithographic projection exposure system comprises using a thermal manipulator to introduce a heating power into the optical element to produce a thermally induced deformation. Before starting operation of the optical system in which useful light impinges on the optical element, the heating power is adjusted with respect to a desired state of the optical element in which a first optical aberration is at least partially compensated. After starting operation of the optical system, the heating power is regulated to the desired state depending on the heat load of the useful light impinging on the optical element. The heating power is regulated in such a way that the average temperature of the optical element remains constant up to a maximum deviation of 0.5 K.

### CROSS-REFERENCE TO RELATED APPLICATIONS

The present application is a continuation of, and claims benefit under 35 USC 120 to, international application No. PCT/EP2023/061647, filed May 3, 2023, which claims benefit under 35 USC 119 of German Application No. 10 2022 114 974.9, filed on Jun. 14, 2022, and German Application No. 10 2022 131 353.0, filed on Nov. 28, 2022. The entire disclosure of each of these applications is incorporated by reference herein.

### FIELD

The disclosure relates to a method for heating an optical element in an optical system, such as in a microlithographic projection exposure apparatus, and to an optical system.

### BACKGROUND

Microlithography is used for producing microstructured components, such as integrated circuits or LCDs, for example. The microlithography process is carried out in a so-called projection exposure apparatus comprising an illumination device and a projection lens. The image of a mask (=reticle) illuminated via the illumination device is projected in this case via the projection lens onto a substrate (for example a silicon wafer) that is coated with a light-sensitive layer (photoresist) and arranged in the image plane of the projection lens in order to transfer the mask structure to the light-sensitive coating of the substrate.

In projection lenses designed for the EUV range, which is to say at wavelengths of for example approximately 13 nm or approximately 7 nm, mirrors are used as optical components for the imaging process owing to the general lack of availability of suitable light-transmissive refractive materials.

On account of manufacturing fluctuations of the mirrors and also finite precision of mounting and/or alignment processes to be carried out during assembly of the projection exposure apparatus, it is possible for there to be unavoidable optical aberrations result owing to the existence of deviations from the ideal optical design. In order to try to correct for such optical aberrations (also referred to as “cold aberrations”), one approach—besides the targeted actuation of the respective mirrors in their rigid body degrees of freedom—is to apply a suitable heating profile to the mirrors in a targeted manner using a heating arrangement (which couples in infrared radiation, for example) in order to achieve a correction of the optical cold aberrations via the thermally induced deformation attained in this way.

As a result inter alia of absorption of the radiation emitted by the EUV light source, the EUV mirrors heat up (also referred to as “mirror heating”) and undergo an associated thermal expansion or deformation, which in turn can result in an impairment of the imaging properties of the optical system. In order to try to address surface deformations caused by heat inputs into an EUV mirror, and attendant optical aberrations, it is known inter alia to use mirror substrate material in the form of an ultra-low expansion material, e.g. a titanium silicate glass sold under the trade name ULE™ by Corning Inc. and to set the so-called zero crossing temperature (ZCT) in a region near the optical effective surface. At this zero crossing temperature, which is approximately ϑ=30° C. for example for ULE™, the coefficient of thermal expansion has in its temperature dependence a zero crossing in the vicinity of which there is no or only a negligible dependence of the thermal expansion of the mirror substrate material on temperature variations that occur. Furthermore, owing to the use of a heating arrangement (e.g. on the basis of infrared radiation), active mirror heating can take place in phases of comparatively low absorption of EUV used radiation, the active mirror heating being correspondingly decreased as the absorption of the EUV used radiation increases.

The above-described approaches firstly for correcting “cold aberrations” and secondly for avoiding deformations induced in the respective mirror (i.e. the “mirror heating”) as a result of impingement of EUV or used light during operation of the optical system in this respect can include opposing or conflicting desired properties since—as indicated in the schematic diagram in FIG. 3A—the temperature ranges or target values that are expedient or favored for each of the two approaches differ from one another. In this regard, for reducing optical aberrations that are thermally induced by EUV radiation during operation of the optical system, a temperature window in the region of the abovementioned zero crossing temperature (=ZCT) can be desirable, cf. the target value designated by 300 in FIG. 3A, this target value being favored with respect to “mirror heating” (MH) and at this target value the thermally induced deformations that occur being as insensitive as reasonably possible in relation to local temperature variations at different mirror positions. By contrast, for the correction effect sought with regard to the “cold aberrations”, it can be desirable for the respective mirror to be heated into a temperature range, cf. the target value designated by 302 in FIG. 3A, this target value being favored with respect to the cold aberration and at this target value the deformation of the mirror being sufficiently sensitive to additional thermal irradiation, as a result of which, however, the aberrations induced as a result of the impingement of EUV light during operation and the influence of “mirror heating” mentioned above can then be in turn intensified.

Even when the heating power introduced into the mirror by a thermal manipulator is set to a target state in which, besides the cold aberrations to be compensated for, the thermal load acting on the mirror as a result of incident used light during operation of the optical system is already taken into account and for which in this respect—as indicated in FIG. 3B on the basis of an optimized target value of the sector heater that is designated by 304—the heating power generated by the thermal manipulator is initially optimized with respect both to the cold aberrations and to the aspect of “mirror heating”, it is possible that, on account of the fundamental departure from the zero crossing temperature (ZCT) mentioned above, the temperature increase accompanying the EUV load during operation inevitably leads to transient aberrations, or aberrations that vary over time right from the beginning of operation (i.e. the start time), cf. the intensification of the MH-induced aberrations that is highlighted as 306 in FIG. 3B, as a result of which the performance of the optical system or of the projection exposure apparatus is impaired.

Reference is made merely by way of example to DE 10 2019 219 289 A1.

### SUMMARY

The present disclosure seeks to provide a method for heating an optical element, such as a microlithographic projection exposure apparatus, and an optical system which can avoid surface deformations caused by heat inputs in the optical element, and attendant optical aberrations.

In accordance with one aspect, the disclosure relates to a method for heating an optical element in an optical system, such as in a microlithographic projection exposure apparatus,
wherein a heating power is introduced into the optical element using a thermal manipulator in order to generate a thermally induced deformation;
wherein before the starting of operation of the optical system in which used light is incident on the optical element, the heating power is set with respect to a target state of the optical element in which a first optical aberration is at least partly compensated for; and
wherein after the starting of operation of the optical system, the heating power is controlled to the target state depending on the thermal load of the used light incident on the optical element, wherein the control takes place in such a way that the average temperature of the optical element remains constant up to a maximum deviation of 0.5 K, for example of 0.2 K at the most.

The first optical aberration can be at least partly caused by manufacturing or alignment. However, the disclosure is not restricted thereto, and so the first optical aberration can also be caused by other fault sources.

In embodiments, the disclosure proceeds from an approach that, in view of the issue (explained in the introduction) of opposing or conflicting desired properties with respect to firstly the temperature range favored for a correction of cold aberrations and secondly the temperature range favored for a compensation of the influence of “mirror heating”, just with the definition of a suitable set of target values of the heating power introduced into the optical element by a thermal manipulator, both aspects “correction of cold aberrations” and “compensation of the influence of mirror heating” are already included. This is done by virtue of the fact that already during the setting of the heating power in addition to the correction of the abovementioned “cold aberrations” the corresponding effect of the heating power on the optical aberration generated owing to incident used light during actual operation of the optical element or of the optical system having this element is taken into account (such as particular by way of a “co-optimization”).

The disclosure is not restricted further with regard to the specific configuration of the thermal manipulator, i.e. the way in which the heating power is introduced into the optical element. Merely by way of example, the heating power can for instance be introduced in a manner known per se via infrared (IR) emitters, wherein individual sectors can also be subjected to IR radiation by way of the setting of corresponding heating profiles. For example, a heating arrangement described in DE 10 2019 219 289 A1 can be used for this purpose. Alternatively, the heating power can also be introduced by way of electrodes to which electrical voltage can be applied and which are arranged on the optical element or mirror to be heated.

In this case, the wording “set of target values” is intended to express the fact that the thermal manipulator can optionally also subject individual sectors to IR radiation in a targeted manner by way of the setting of corresponding heating profiles (e.g. using the heating arrangement described in DE 10 2019 219 289 A1). In this respect, the “set of target values” for the heating power of the thermal manipulator optionally comprises a value for each of the sectors (in the manner of a vector having a plurality of components).

The first optical aberration (caused by manufacturing or alignment, for example) may be brought about by the optical element itself or elsewhere in the optical system (by some other optical element, for example).

Proceeding from the approach mentioned above, the disclosure can involve the further concept that the heating power of the thermal manipulator set at the beginning of operation for example with regard to the correction of cold aberrations as described above, during operation of the optical system, is not kept constant over time for instance, but rather is readjusted depending on the thermal load of the used light incident on the optical element.

In this case, in embodiments, a way in which a concept according to the disclosure differs from conventional preheating approaches in that, during the operation of the optical system, for instance a homogeneous or constant temperature distribution within the optical element or mirror is not sought, rather—taking existing cold aberrations into account—a constant wavefront effect is maintained, which can be effected in turn by the generation of a correspondingly inhomogeneous heating profile within the mirror and optionally also by the maintenance of this inhomogeneous heating profile under used load by way of a readjustment of the heating power in the course of operation of the optical system.

Furthermore, according to the disclosure, the heating power is intended to be controlled in such a way that the average temperature of the optical element remains constant up to a maximum deviation of 0.5 K, such as of 0.2 K at the most. In this case, the disclosure includes the further concept of ensuring in the course of control that the average temperature of the optical element remains substantially constant over the entire time period from an initial state—i.e. the state before the impingement of (e.g. EUV) used light—to the state during the impingement of (e.g. EUV) used light during the operation of the optical system, in order in this respect to avoid or at least reduce “overshoots”. This condition of maintaining the average temperature of the optical element over time can in this case influence the control of the heating power as a constraint. Furthermore, different illumination settings can also be taken into account in this case. In other words, for each illumination setting, the corresponding set of target values for the heating power of the thermal manipulator, in the control of the heating power, can be chosen such that in each case the average temperature of the optical element is maintained over the time period from the initial state or the state before the impingement of (e.g. EUV) used light during the operation of the optical system to the state during the impingement of (e.g. EUV) used light during the operation of the optical system.

In accordance with a more general aspect of the disclosure, however, the control can also be effected differently, such as without or without continuous limitation of the deviation of the average temperature of the optical element to a specific maximum value or else with a restriction of the deviation of the average temperature to a higher maximum value than the aforementioned 0.5 K and 0.2 K.

A readjustment according to the disclosure of the heating power of the thermal manipulator can be effected in various ways according to the disclosure, as described below. In this respect, the disclosure first encompasses embodiments with a temperature-based control concept, which can in turn be based on the ascertainment of an average temperature at the optical effective surface or alternatively also based on a temperature distribution at the optical effective surface (which involves optionally taking as a basis different temperature values for different sectors at the optical effective surface). Furthermore, the disclosure also encompasses embodiments in which the readjustment according to the disclosure is effected on the basis of a wavefront effect (estimated using at least one wavefront sensor and/or in a model-assisted manner) of the optical element or of the associated optical system.

In accordance with one embodiment, the optical system has at least one further mirror that is actuable in a plurality of degrees of freedom, for example a plurality of further mirrors that are each actuable in a plurality of degrees of freedom, wherein the totality of these degrees of freedom is used for the at least partial compensation of the first optical aberration.

In accordance with one embodiment, the heating power is set before the starting of operation of the optical system by way of additionally taking account of the respective effect of the heating power on a second optical aberration caused by used light incident on the optical element during subsequent operation of the optical system. In other words, before the starting of operation of the optical system, the heating power, as already mentioned, is set with the aim of a co-optimization both with respect to the cold aberrations and with respect to the “mirror heating” that takes place during subsequent operation owing to the EUV load.

In accordance with one embodiment, the target state is defined by a thermal state of the optical element.

In accordance with one embodiment, the target state is defined by a wavefront provided in an image plane by the optical system.

In accordance with one embodiment, the heating power is controlled after the starting of operation of the optical system on the basis of at least one temperature measured using at least one temperature measuring device. The temperature measuring device can be configured in any suitable manner, e.g. as a temperature sensor or thermal imaging camera.

In accordance with one embodiment, the heating power is controlled after the starting of operation of the optical system on the basis of at least one average temperature at the optical effective surface of the optical element that is estimated using at least one temperature measuring device.

In accordance with one embodiment, the heating power is controlled after the starting of operation of the optical system on the basis of a temperature distribution at the optical effective surface of the optical element that is estimated using one or more temperature measuring devices.

In accordance with one embodiment, the temperature distribution at the optical effective surface of the optical element is estimated from measurement signals supplied by the temperature measuring devices on the basis of a model using an observer.

In accordance with one embodiment, the heating power is controlled after the starting of operation of the optical system on the basis of an estimation of the wavefront effect of the optical system, such as on the basis of a feedforward model.

In accordance with one embodiment, the estimation of the wavefront effect of the optical element is effected using at least one wavefront sensor.

In accordance with one embodiment, the estimation of the wavefront effect of the optical element is effected on the basis of target values for the heating power set by the thermal manipulator.

In accordance with one embodiment, the estimation of the wavefront effect of the optical element is effected on the basis of a combination of wavefront and temperature measurements.

In accordance with one embodiment, information about the reticle used, the illumination setting used and/or information from an intensity measurement are/is used in the feedforward model. The information about the reticle used can in this case can concern information about the optical far field which is generated by diffraction of the (e.g. EUV) used light at the structures of the reticle during operation of the optical system and which can be ascertained by optical forward simulation. The information from an intensity measurement can concern the intensity of the radiation of the thermal manipulator (e.g. infrared laser) used for generating the heating power.

In accordance with one embodiment, the control of the heating power is carried out transiently on the basis of the feedforward model. Here the temperature distribution in the optical element that is suitable for setting the target state or the desired wavefront can be set transiently or determined anew in each case at different times during operation of the optical system.

In accordance with one embodiment, this transient control on the basis of the feedforward model is carried out as model-predictive control for taking account of a change of the reticle used and/or of the illumination setting used. In other words, a change of the reticle used and/or of the illumination setting used can be anticipated in order in this respect to avoid the occurrence of overshoots after this change.

In accordance with one embodiment, a combination of a plurality of mirrors is used in the control, wherein this plurality comprises at least one mirror in which a heating profile complementary to a temperature distribution caused by used light incident on this mirror is generated by way of a heating device, and at least one mirror which is actively deformed for wavefront manipulation.

The control variants above, if implemented, can be carried out in addition to the abovementioned control to a maximum permissible deviation of the average temperature of the optical element. In the context of a general aspect of the present disclosure, however, the control variants above can also be implemented individually or in combination independently of a restriction to a maximum average temperature deviation.

In accordance with one embodiment, the optical element is a mirror.

In accordance with one embodiment, the optical system is designed for an operating wavelength of less than 400 nm, such as less than 250 nm, for example less than 200 nm.

In accordance with one embodiment, the optical element is designed for an operating wavelength of less than 30 nm, such as less than 15 nm.

The disclosure further also relates to an optical system, such as in a microlithographic projection exposure apparatus, comprising
at least one optical element,
   a thermal manipulator for heating this optical element; and
   a control unit for controlling the heating power introduced into the optical element by the thermal manipulator,
   wherein this control is effected on the basis of a target state in which a first optical aberration is at least partly compensated for, and depending on the thermal load of the used light incident on the optical element, wherein the heating power is controlled in such a way that the average temperature of the optical element remains constant up to a maximum deviation of 0.5 K, such as of 0.2 K at the most.

In accordance with a more general aspect of the disclosure, however, in the case of the optical system, the control can also be effected differently, for example without or without continuous limitation of the deviation of the average temperature of the optical element to a specific maximum value or else with a restriction of the deviation of the average temperature to a higher maximum value than the aforementioned 0.5 K and 0.2 K.

In accordance with one embodiment, the first optical aberration is at least partly caused by manufacturing or alignment.

In accordance with one embodiment, the optical system is configured to carry out a method having the features described above. With regard to features and further configurations of the optical system, reference is made to the abovementioned explanations in association with the method according to the disclosure.

Further configurations of the disclosure can be gathered from the description and the dependent claims.

The disclosure is explained in greater detail below on the basis of exemplary embodiments illustrated in the accompanying figures.

### BRIEF DESCRIPTION OF THE DRAWINGS

In the figures:

FIG. 1 shows a schematic illustration of the possible setup of a microlithographic projection exposure apparatus designed for operation in the EUV;

FIG. 2 shows a schematic illustration for explaining one possible realization of a method according to the disclosure; and

FIGS. 3A-3B show diagrams for explaining an issue considered in the present disclosure.

### DETAILED DESCRIPTION

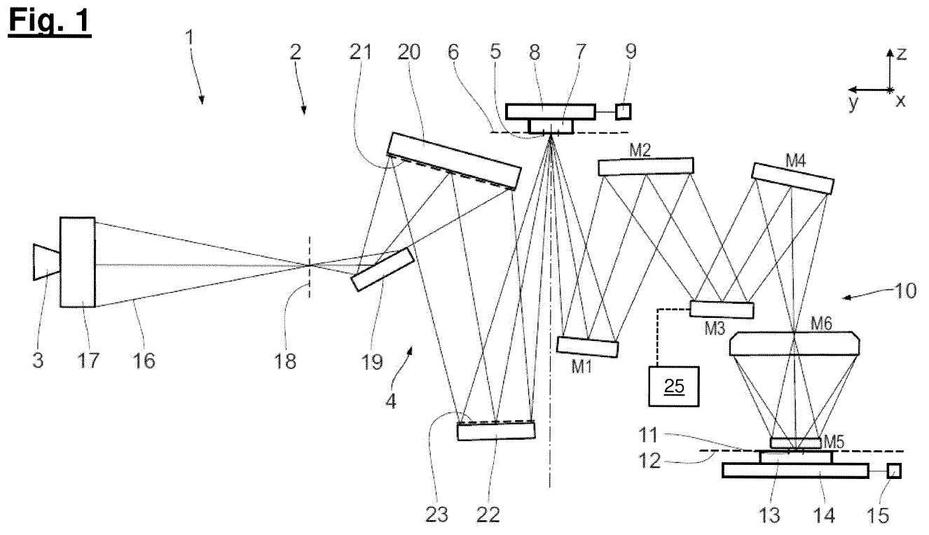

FIG. 1 firstly shows a schematic illustration of a projection exposure apparatus 1 which is designed for operation in the EUV and in which the disclosure is able to be realized by way of example.

In accordance with FIG. 1, the projection exposure apparatus 1 comprises an illumination device 2 and a projection lens 10. The illumination device 2 serves to illuminate an object field 5 in an object plane 6 with radiation from a radiation source 3 by way of an illumination optical unit 4. What is exposed here is a reticle 7 disposed in the object field 5. The reticle 7 is held by a reticle holder 8. The reticle holder 8 is displaceable by way of a reticle displacement drive 9 such as in a scanning direction. For explanation purposes, a Cartesian xyz-coordinate system is depicted in FIG. 1. The x-direction runs perpendicularly to the plane of the drawing into the latter. The y-direction runs horizontally, and the z-direction runs vertically. The scanning direction runs along the y-direction in FIG. 1. The z-direction runs perpendicularly to the object plane 6.

The projection lens 10 serves for imaging the object field 5 into an image field 11 in an image plane 12. A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15 for example along the y-direction. The displacement, firstly, of the reticle 7 by way of the reticle displacement drive 9 and, secondly, of the wafer 13 by way of the wafer displacement drive 15 can be synchronized with one another.

The radiation source 3 is an EUV radiation source. The radiation source 3 emits EUV radiation, which is also referred to below as used radiation or illumination radiation. For example, the used radiation has a wavelength in the range of between 5 nm and 30 nm. The radiation source 3 can be for example a plasma source, a synchrotron-based radiation source or a free electron laser (FEL). The illumination radiation 16 emanating from the radiation source 3 is focused by a collector 17 and propagates through an intermediate focus in an intermediate focal plane 18 into the illumination optical unit 4. The illumination optical unit 4 comprises a deflection mirror 19 and, disposed downstream thereof in the beam path, a first facet mirror 20 (having schematically indicated facets 21) and a second facet mirror 22 (having schematically indicated facets 23).

The projection lens 10 comprises a plurality of mirrors Mi (i=1, 2, . . . ), which are consecutively numbered according to their arrangement in the beam path of the projection exposure apparatus 1. In the example illustrated in FIG. 1, the projection lens 10 comprises six mirrors M1 to M6. Alternatives with four, eight, ten, twelve, or any other number of mirrors Mi are likewise possible. The penultimate mirror M5 and the last mirror M6 each have a through opening for the illumination radiation 16. The projection lens 10 is a doubly obscured optical unit. The projection lens 10 has an image-side numerical aperture which, merely by way of example, may be greater than 0.3, and may also be greater than 0.5 and more particularly greater than 0.6.

During operation of the microlithographic projection exposure apparatus 1, the electromagnetic radiation incident on the optical effective surface of the mirrors is partly absorbed and, as explained in the introduction, results in heating and an associated thermal expansion or deformation, which can in turn result in an impairment of the imaging properties of the optical system. By way of a thermal manipulator in the form of a heating arrangement, as described in the introduction, active mirror heating can then take place in each case in phases of comparatively low absorption of EUV used radiation, the active mirror heating being correspondingly decreased as the absorption of the EUV used radiation increases.

A heating arrangement is depicted merely schematically in FIG. 1 and denoted by “25”, this heating arrangement 25 being used to introduce a heating power into the mirror M3 in the example. In this case, the disclosure is not further restricted with regard to the way in which heating power is introduced or the configuration of the heating arrangement used to this end. Purely by way of example, the heating power can be introduced in a manner known per se by way of infrared emitters or else by way of electrodes to which a voltage can be applied and which are arranged on the optical element or mirror to be heated.

Furthermore, the disclosure is not further restricted with regard to the number of optical elements or mirrors to be heated, with the result that the control according to the disclosure can be applied to the heating of only a single optical element or else to the heating of a plurality of optical elements.

An aspect that is common to the embodiments described below is that a heating power is not just introduced into an optical element or a mirror by way of (initial) setting to a target state taking account of optical aberrations to be compensated for owing to manufacturing or alignment faults and also optionally taking account of the effects of the heating power on a second optical aberration caused by “mirror heating” during subsequent operation, rather that in addition—after the starting of operation of the optical system or the impingement of used light on the optical element—the heating power is also controlled depending on the thermal load of the used light (i.e. the EUV radiation) incident on the optical element.

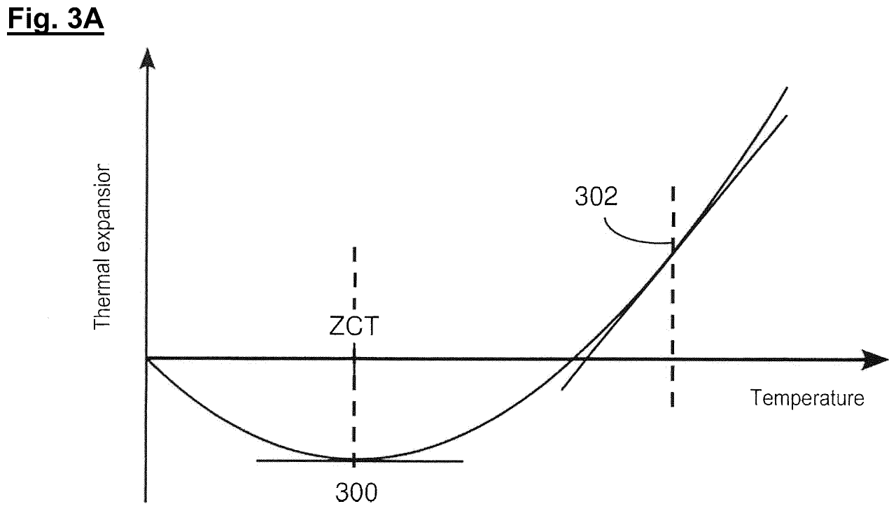

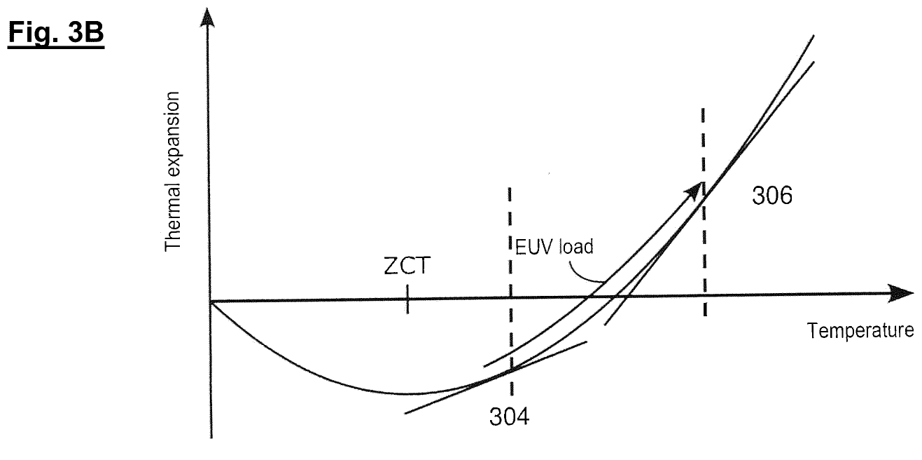

For example, what thus can be taken into account according to the disclosure is that in a projection exposure apparatus, during the microlithographic exposure process, besides the heating power introduced into a mirror by way of IR radiation, for example, used light in the form of EUV radiation also affects the mirror surface with the consequence that the mirror temperature at the optical effective surface increases locally and depending on the chosen illumination setting by comparison with the temperature profile present without EUV radiation, as has already been explained with reference to FIG. 3B.

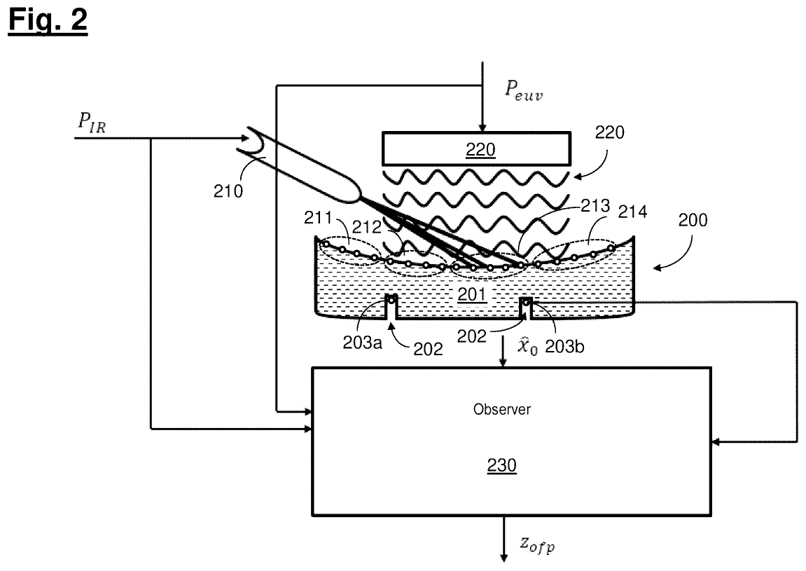

In order to take account of this effect, various control concepts according to the disclosure are described below, temperature-based control concepts firstly being explained with reference to FIG. 2. For this purpose, in the relevant optical element or mirror 200, in a manner known per se, one or more temperature measuring devices 203a, 203b (e.g. temperature sensors) are arranged in access channels 202 situated within the mirror substrate 201, these temperature measuring devices 203a, 203b being used to estimate the average temperature or else a temperature distribution at the optical effective surface of the mirror 200.

In FIG. 2, furthermore, a thermal manipulator in the form of an infrared heating arrangement is designated by “210” and the EUV radiation (=used light) acting on the mirror 200 during operation is designated by “220”. Moreover, a plurality of sectors in the region of the optical effective surface of the mirror are designated by “211” to “214”, wherein in embodiments, given the presence of a sufficient number of temperature measuring devices 203a, 203b and optionally also using an observer 230 and on the basis of a model, an estimation of a local temperature distribution at the optical effective surface of the mirror 200 can be performed.

In a first embodiment of a temperature-based control concept according to the present disclosure, the heating power fed to the mirror 200 after the starting of operation by way of the thermal manipulator 210 can be controlled on the basis of the estimated average temperature at the optical effective surface (i.e. firstly still dispensing with a spatially resolved determination of the temperature distribution over a plurality of sectors). This approach is based on the observation that, in a simplified consideration, the EUV radiation 220 absorbed by the mirror 200 leads to an increase in the average mirror temperature:

$$\overline{{T}_{g e s}} = \overline{{T}_{IR} + {T}_{EUV}} \qquad ( 1 )$$

It will now be assumed below that the thermal manipulator 210 is configured as a “sector heater” insofar as it enables heating power to be introduced into the mirror 200 in a targeted manner into different sectors (e.g. “211” to “214” in accordance with FIG. 2). For example, a heating arrangement described in DE 10 2019 219 289 A1 can be used for this purpose.

In accordance with the first embodiment, after the estimation of the average temperature at the optical effective surface of the mirror 200, the heating power can then be controlled to the effect that the average temperature is kept constant during operation and while EUV radiation 220 acts on the mirror 200. This can alternatively first take place in such a manner that the thermal regulator 210 or IR radiant heater enables corresponding homogeneous heating of the optical effective surface, which can be correspondingly controlled downward in the course of the increase in the average mirror temperature associated with the EUV radiation 220. Alternatively, by way of the individual by the IR radiant heater configured as a sector heater, heating power can also be subtracted in such a way as to attain overall a decrease in the average temperature at the optical effective surface while maintaining the inhomogeneous heating profile introduced by way of the thermal manipulator 210 or IR radiant heater. This can be effected e.g. by way of a global scaling factor S in accordance with

$$\overline{{T}_{S \cdot {P}_{1} , … , S \cdot {P}_{N}} + {T}_{e u v}} = \overline{{T}_{i n i t}} . \qquad ( 2 )$$

Alternatively, a linear combination of heating powers introduced per sector can also be determined, which generates as homogeneous a temperature increase as possible and can then be used for the control according to the disclosure. Instead of a global scaling factor, other suitable mathematical approaches can also be used for reducing the average temperature at the optical effective surface.

In order to realize the above-described temperature-based control concept on the basis of the average temperature at the optical effective surface, a sufficiently large offset of the average temperature at the optical effective surface can already kept available during initial setting of the heating power of the thermal manipulator 210 (by way of a co-optimization of the corresponding merit function both with respect to cold aberrations and with respect to “mirror heating”). In other words, the (average) temperature at the optical effective surface that initially results in accordance with the correspondingly “co-optimized” target value for the heating power, in each sector, should generally be greater than the temperature maximally caused by UV radiation 220 in this sector. In individual cases, for example depending on the specific expansion behavior of the optical element (position of the ZCT), it may be expedient to effect heating with less than the temperature maximally caused by EUV radiation 220.

As already mentioned, in further embodiments, the temperature-based control concept can be extended insofar as the temperature for the individual sectors 211, 212, 213, 214 at the optical effective surface is kept constant over time in relation to the respective initial value (i.e. the temperature value set by way of the thermal manipulator 210 upon the starting of operation). Thus, not just the average temperature of the mirror 200 is kept constant over time, rather to a first approximation the spatial temperature distribution desired for correcting the cold aberrations is also kept constant. Since typically owing to boundary conditions in the optical system the number of temperature measuring devices 203a, 203b, . . . that can be integrated in the mirror 200 is limited and sometimes N>K holds true (where N denotes the number of sectors 211, 212, . . . and K denotes the number of temperature measuring devices 203a, 203b, . . . ), in embodiments of the disclosure an observer 230 in accordance with FIG. 2 can additionally used in order to estimate the temperature distribution in the individual sectors 211, 212, . . . on the basis of the temperature measurement values and additionally on the basis of a process model. The estimation quality achievable here is dependent both on the quality of the process model and on the knowledge of the input signals. In order to improve the estimation quality, the EUV load (as significant thermal load) can also be fed to the observer 230.

In further embodiments, the control according to the disclosure of the heating power coupled into the optical element or the mirror 200 by way of the thermal manipulator 210 during operation can also be effected in a wavefront-based manner, i.e. the heating profile set by way of the thermal manipulator 210—once again configured as a sector heater—is optimized directly with respect to the wavefront generated by the mirror 200 or the associated optical system. In this case, the present wavefront effect can be respectively captured or estimated using a wavefront sensor (arranged in the region of the wafer stage, for example) and optionally additionally using a feedforward model. Since this wavefront-based approach does not pursue the aim of keeping constant the initial temperature distribution (i.e. the temperature distribution set upon the starting of operation or at the beginning of the impingement of used light or EUV radiation 220 on the mirror 200) in accordance with the target value for the heating power set for correcting the cold aberrations, but rather pursues the aim of directly keeping constant the wavefront effect of the mirror, significant deviations from the initial temperature distribution may arise.

The corresponding wavefront-based optimization can be effected by minimization of a merit function in which, for a predefined disturbance S, a wavefront effect l(\vec{x}) of the position and orientation of the optical elements \vec{x}, a further wavefront effect f(\vec{h}) of the thermal manipulator or sector heater, and also an (heating power) amplitude \vec{h} set by way of the thermal manipulator, a scalar value is assigned by way of a weighting metric D. The wavefront-based optimization then corresponds to a minimization of this merit function in accordance with

$$\vec{{x}^{*}} , \vec{{h}^{*}} = {arg min}_{\vec{x} , \vec{h}} D ( S + l ( \vec{x} ) + f ( \vec{h} ) ) . \qquad ( 3 )$$

The disclosure then extends this merit function for transient, wavefront-based “co-optimization” by prediction of the wavefront effect f(\vec{h}) introduced by the thermal manipulator or sector heater and of the aberrations Z(\vec{h}, t)_{FF,MH} induced by “mirror heating” owing to EUV load:

$$\vec{{x}^{*}} ( t ) , \vec{{h}^{*}} ( t ) = arg {min}_{\vec{x} , \vec{h}} D ( S + l ( \vec{x} ) + f ( \vec{h} ) + {Z ( \vec{h} , t )}_{FF , MH} ) \qquad ( 4 )$$

In this case, the disturbance S can be determined by way of an initial wavefront measurement and be updated repeatedly on the basis of further wavefront measurements. Alternatively, the disturbance S can also be ascertained by simulations. The delay in the heating-up and cooling-down behavior of the sector heater can be taken into account in the optimization. A feedforward model can be used to predict the respective wavefront effect between the respective wavefront measurements as well. Furthermore, the feedforward model can also be used for model-based predictive control in order that the heating power introduced by way of the thermal manipulator or sector heater, in the event of an imminent setting change, is already prepared for the new EUV load.

Even though the disclosure has been described on the basis of specific embodiments, numerous variations and alternative embodiments are evident to a person skilled in the art, e.g. through combination and/or exchange of features of individual embodiments. Accordingly, it goes without saying for a person skilled in the art that such variations and alternative embodiments are concomitantly encompassed by the present disclosure, and the scope of the disclosure is restricted only within the meaning of the appended patent claims and the equivalents thereof.

What is claimed is:

1. A method of using a sector heater to heat an optical element in an optical system, the method comprising:
a) before impinging used light on the optical element during operation of the optical system, setting a heating power to be introduced into different sectors of the optical element by the sector heater with respect to a target state of the optical element to at least partially compensate for a first optical aberration; and
b) when operating the system while the used light impinges on the optical element, controlling the heating power introduced into the different sectors of the optical element by the sector heater to achieve the target state based on: i) a thermal load of the used light incident on the optical element; and ii) an estimation of a wavefront effect of the optical system.

2. The method of claim 1, wherein the first optical aberration is at least partly caused by manufacturing of the optical element or by alignment of the optical element.

3. The method of claim 1, wherein the optical system further comprises a mirror that is actuatable in a plurality of degrees of freedom to at least partially compensate for the first optical aberration.

4. The method of claim 1, wherein setting the heating power in a) comprises taking account of an effect of the heating power on a second optical aberration caused by the used light incident on the optical element that will occur during b).

5. The method of claim 1, wherein the target state is defined by a thermal state of the optical element.

6. The method of claim 1, wherein the target state is defined by a wavefront provided in an image plane of the optical system.

7. The method of claim 1, wherein b) comprises controlling the heating based on at least one temperature measured using at least one temperature measuring device.

8. The method of claim 1, wherein b) comprises controlling the heating power on the basis of at least one average temperature at the optical effective surface of the optical element that is estimated using at least one temperature measuring device.

9. The method of claim 1, wherein b) comprises controlling the heating power on the basis of a temperature distribution at the optical effective surface of the optical element that is estimated using one or more temperature measuring devices.

10. The method of claim 9, wherein the temperature distribution at the optical effective surface of the optical element is estimated from measurement signals supplied by the temperature measuring devices on the basis of a model using an observer.

11. The method of claim 1, comprising using at least one wavefront sensor to estimate the wavefront effect of the optical element.

12. The method of claim 1, comprising estimating the wavefront effect of the optical element on the basis of target values for the heating power set by the sector heater.

13. The method of claim 1, comprising estimating the wavefront effect of the optical element on the basis of a combination of wavefront and temperature measurements.

14. The method of claim 1, wherein:
controlling the heating power during b) comprises using a combination of a plurality of mirrors;
the plurality of mirrors comprises a first mirror having a heating profile generated by the sector heater that is complementary to a temperature distribution caused by the used light incident on the first mirror; and
the plurality of mirrors comprises a second mirror which is actively deformable to manipulate the wavefront.

15. The method of claim 1, wherein the optical element comprises a mirror.

16. The method of claim 1, wherein the used light has a wavelength of less than 400 nm.

17. The method of claim 1, wherein the used light has a wavelength of less than 30 nm.

18. The method of claim 1, wherein b) comprises controlling the heating power so that an average temperature of the optical element is constant to within 0.5 K.

19. The method of claim 1, wherein b) comprises controlling the heating power introduced into the different sectors of the optical element by the sector heater to achieve the target state based on a feedforward model.

20. The method of claim 1, wherein b) comprises transiently controlling the heating power based on the feedforward model.

21. The method of claim 20, comprising transiently controlling as model-predictive control to take into account a change of a reticle used and/or of an illumination setting used.

22. The method of claim 21, comprising using information about the reticle, an illumination setting and/or an intensity measurement in the feedforward model.

23. An optical system, comprising:
an optical element;
a sector heater configured to introduce a heating power into different sectors of the optical element in a targeted manner; and
a control unit configured to control the heating power introduced into the optical element by the sector heater based on a target state in which a first optical aberration is at least partly compensated for and a thermal load of used light incident on the optical element during use of the optical system,
wherein the controller is configured so that, when operating the system while the used light impinges on the optical element, the controller controls the heating power introduced into the different sectors of the optical element by the sector heater to achieve the target state based on: i) a thermal load of the used light incident on the optical element; and ii) an estimation of a wavefront effect of the optical system.
